(19) United States
(12) Patent Application Publication
(10) Pub. No.: US 2010/0072454 A1
(43) Pub. Date: Mar. 25, 2010

(54) EXPOSURE METHOD, AND SEMICONDUCTOR DEVICE

(76) Inventors: Ryota Aburada, Kawasaki-shi (JP); Satoshi Tanaka, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/500,208

(22) Filed: Jul. 9, 2009

(30) Foreign Application Priority Data
Sep. 22, 2008 (JP) 2008-242093

(51) Int. Cl. H01L 45/00; G03B 27/32

(52) U.S. Cl. 257/5; 355/77; 257/E45.002

(57) ABSTRACT

An exposure method includes an exposure process for exposing a substrate through a halftone mask with quadrupole illumination to form plural columnar portions that are disposed into a matrix shape in a first direction and a second direction orthogonal to the first direction. The halftone mask includes a first pattern that is extended in the first direction and disposed at predetermined pitches in the second direction; and a second pattern that is extended in the second direction and disposed at predetermined pitches in the first direction such that an intersection portion intersecting the first pattern is formed. The pitches and widths of the patterns on the halftone mask are configured such that zero-order diffracted light intensity and first-order diffracted light intensity, diffracted by the halftone mask, are substantially matched with each other and such that a first-order diffracted light phase is inverted with respect to a zero-order diffracted light phase.

### CROSS-REFERENCE TO RELATED APPLICATIONS

This application is based upon and claims the benefit of priority from the prior Japanese Patent Application No. 2008-242093, filed on Sep. 22, 2008, the entire contents of which are incorporated herein by reference.

### BACKGROUND OF THE INVENTION

1. Field of the Invention

The present invention relates to an exposure method used in a semiconductor lithography process, and a semiconductor device formed by the exposure method.

2. Description of the Related Art

Recently, with finer pitch of LSI, the minimum line width of a semiconductor circuit is required to be half or less of a light source wavelength of an exposure apparatus that is mainly used for production.

A resistance-change type memory in which a variable resistive element is used as a memory cell has been proposed as a technique of realizing the finer memory cell. Examples of the variable resistive element include a phase-change memory device in which a resistance value is changed by a phase change between crystalline and amorphous states of a chalcogenide compound, an MRAM device in which a resistance change caused by a tunnel magnetoresistance effect is used, a polymer ferroelectric RAM (PFRAM) memory device in which a resistance element is formed by a ferroelectric polymer, and an ReRAM device in which a resistance change is generated by application of an electric pulse (for example, see Japanese Patent Application Laid-Open No. 2006-344349, paragraph [0021]).

In the resistance-change type memory, the memory cell can be formed by a series-connected circuit of a Schottky diode and a resistance-change element instead of a transistor. Therefore, in the resistance-change type memory, advantageously lamination is easy to achieve and higher integration is realized by a three-dimensional structure (for example, see Japanese Patent Application Laid-Open No. 2005-522045).

The resistance-change type memory has a columnar portion that acts as the memory cell connecting a bit line and a word line. There is a need for improving a yield in forming the columnar portion.

### SUMMARY OF THE INVENTION

An exposure method according to a first aspect of the invention includes an exposure process for exposing a substrate through a halftone mask with quadrupole illumination to form a plurality of columnar portions that are disposed into a matrix shape in a first direction and a second direction orthogonal to the first direction, the halftone mask including: a first pattern extended in the first direction and disposed at predetermined pitches in the second direction; and a second pattern extended in the second direction and disposed at predetermined pitches in the first direction such that an intersection portion intersecting the first pattern is formed, and the pitches and widths of the patterns on the halftone mask being configured such that zero-order diffracted light intensity and first-order diffracted light intensity, which are diffracted by the halftone mask, are substantially matched with each other and such that a first-order diffracted light phase is inverted with respect to a zero-order diffracted light phase.

A semiconductor device according to a third aspect of the invention comprising a plurality of columnar portions extended in a direction perpendicular to a substrate, and disposed into a matrix shape at equal pitches in a predetermined region, wherein relationships expressed by (Formula 2) and (Formula 3) are satisfied:

1.1μ₂>μ₁>μ₂ (Formula 2)

0<α₁−α₂ (Formula 3)

where μ₁ is an average value of diameters of the columnar portions formed in an end portion of the predetermined region, α₁ is a variation of diameters of the columnar portions formed in the end portion of the predetermined region, μ₂ is an average value of diameters of the columnar portions formed in a portion except for the end portion of the predetermined region, and α₂ is a variation of diameters of the columnar portions formed in a portion except for the end portion of the predetermined region.

### BRIEF DESCRIPTION OF THE DRAWINGS

FIG. 1 is a perspective view illustrating a semiconductor device according to a first embodiment of the invention;

FIG. 2A is a plan view illustrating the semiconductor device of FIG. 1;

FIG. 2B is an enlarged view illustrating the semiconductor device of FIG. 2A while part of the semiconductor device is omitted;

FIG. 3 is a sectional view illustrating a semiconductor device of the first embodiment;

FIG. 4 schematically illustrates an exposure apparatus 20 used in an exposure method of the first embodiment;

FIG. 5 illustrates an example of quadrupole illumination;

FIG. 6 is a plan view illustrating a halftone mask 30 used in the exposure method of the first embodiment;

FIG. 7 is an enlarged view illustrating the halftone mask 30 of FIG. 6;

FIG. 8 illustrates a functions of g(Xₛ), f₁(Xₛ) to f₃(Xₛ), fₐ(Xₛ), and f_{b}(Xₛ);

FIG. 9 is a sectional view illustrating a process for producing the semiconductor device of the first embodiment;

FIG. 10 is a sectional view illustrating a process for producing the semiconductor device of the first embodiment;

FIG. 11 is a sectional view illustrating a process for producing the semiconductor device of the first embodiment;

FIG. 12 is a sectional view illustrating a process for producing the semiconductor device of the first embodiment;

FIG. 13 is a sectional view illustrating a process for producing the semiconductor device of the first embodiment;

FIG. 14 is a sectional view illustrating a process for producing the semiconductor device of the first embodiment;

FIG. 15 is a sectional view illustrating a process for producing the semiconductor device of the first embodiment;

FIG. 16 is a plan view illustrating a halftone mask 30A according to a second embodiment of the invention;

FIG. 17 is an enlarged view illustrating the halftone mask 30A of FIG. 16;

FIG. 18 illustrates a level line of a value h(Xₛ,Xₒ);

FIG. 19 illustrates a halftone mask 30B according to a third embodiment of the invention;

FIG. 20 is an enlarged view illustrating the halftone mask 30B of FIG. 19;

FIG. 21 illustrates a halftone mask 30C according to a fourth embodiment of the invention;

FIG. 22 is an enlarged view illustrating a neighborhood of an intersection portion 33 of FIG. 21; and

FIG. 23 is an enlarged view illustrating a neighborhood of an intersection portion 33 of the halftone mask according to another embodiment of the invention.

### DETAILED DESCRIPTION OF THE EMBODIMENTS

An exemplary embodiment of the invention will be described with reference to the drawings.

### First Embodiment

### Semiconductor Device of First Embodiment

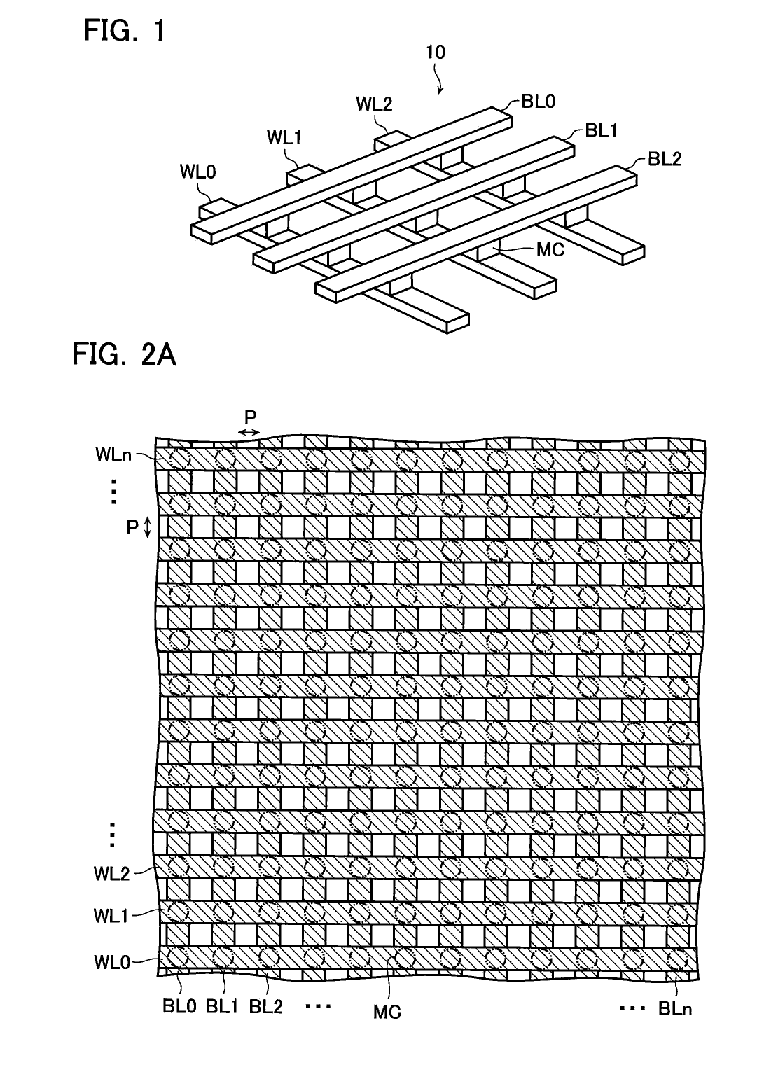

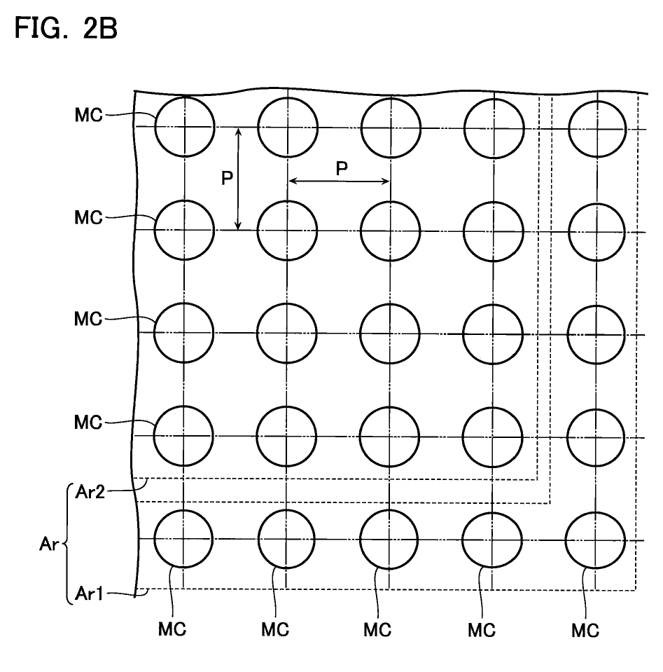

A schematic configuration of a semiconductor device according to a first embodiment of the invention will be described below with reference to FIGS. 1, 2A, and 2B. FIG. 1 is a perspective view of a semiconductor device (memory cell array 10), FIG. 2A is a plan view illustrating the semiconductor device of FIG. 1, and FIG. 2B is an enlarged view illustrating the semiconductor device of FIG. 2A while part of the semiconductor device is omitted.

Referring to FIGS. 1 and 2A, the memory cell array 10 includes plural word lines WLoi (in FIG. 1, i=0 to 2) and plural bit lines BLi (in FIG. 1, i=0 to 2). In FIG. 1, the number of lines i ranges zero to two by way of example. Alternatively, the number of lines i may be at least three.

The plural word lines WLi are arrayed in parallel with one another. The plural bit lines BLi are arrayed in parallel with one another while intersecting the plural word lines WLi. A memory cell MC (columnar portion) is disposed at each intersection portion so as to be sandwiched between the word line WLi and the bit line BLi. Desirably the word line WLi and the bit line BLi are made of a heat-resistant material having a low resistance. Examples of the material include W, WSi, Nisi, and CoSi. The memory cell MC is formed by a series-connected circuit including a variable resistive element and a non-ohmic element.

As illustrated in FIGS. 2A and 2B, the plural memory cells MC (columnar portion) are disposed into a matrix shape at equal pitches P in a predetermined region Ar. The memory cell MC (columnar portion) is formed by an exposure method of the first embodiment.

As illustrated in FIG. 2B, it is assumed that μ₁ is an average value of diameters of the memory cells MC formed in an end portion Ar1 of the predetermined region Ar and α₁ is a variation in diameters of the memory cells MC in the end portion Ar1. It is assumed that μ₂ is an average value of diameters of the memory cells MC formed in a portion Ar2 except for the end portion Ar1 of the predetermined region Ar and α₂ is a variation in diameters of the memory cells MC in the portion Ar2. At this point, the average values μ₁ and μ₂ and the variations α₁ and α₂ satisfy relationships expressed by (Formula 1) and (Formula 2). For example, the variation in diameters of the plural memory cells MC (columnar portion) is set to ±10%.

1.1μ₂>μ₁>μ₂ (Formula 1)

0<α₁−α₂ (Formula 2)

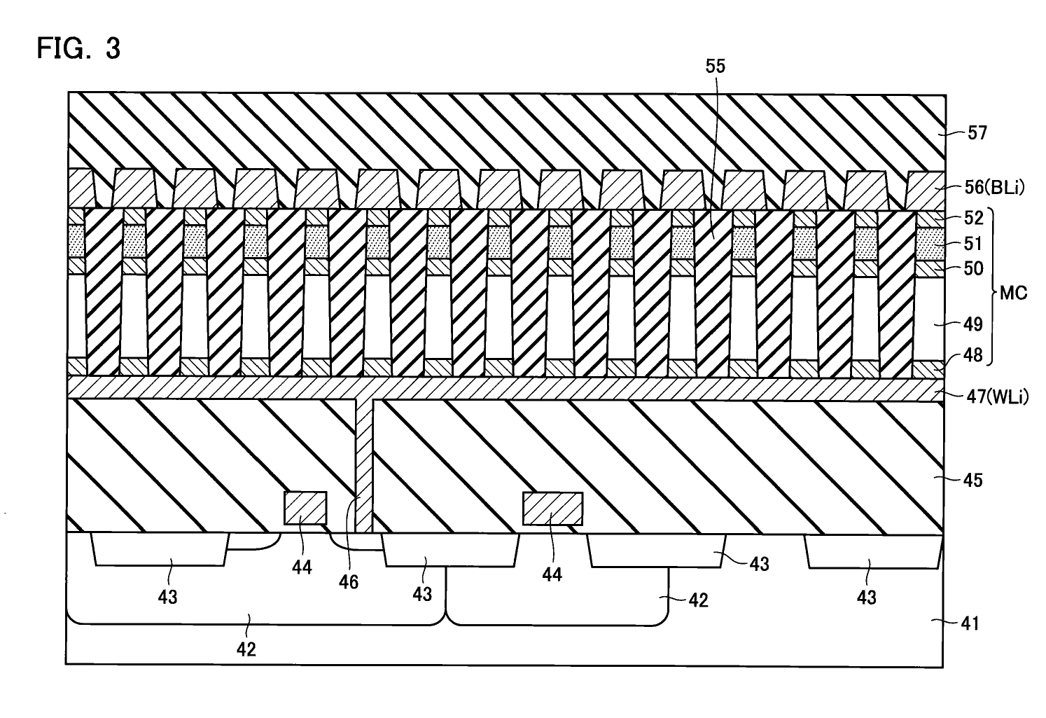

A sectional structure of the semiconductor device will be described with reference to FIG. 3. FIG. 3 is a sectional view illustrating the semiconductor device of the first embodiment. Referring to FIG. 3, an impurity diffused layer 43 and a gate electrode 44 on a silicon substrate 41 in which a well 42 is formed. A transistor including the impurity diffused layer 43 and the gate electrode 44 constitutes a peripheral circuit. A first interlayer insulator 45 is deposited on the impurity diffused layer 43 and the gate electrode 44. A via 46 reaching a surface of the silicon substrate 41 is appropriately formed in the first interlayer insulator 45. A first metal 47 constituting the word line WLi is formed on the first interlayer insulator 45, and the first metal 47 is made of low-resistance material such as tungsten (W). A barrier metal 48 is formed on the first metal 47. The barrier metal can be made of one of or both Ti and TiN. A non-ohmic element 49 such as a diode is formed above the barrier metal 48.

A first electrode 50, a variable resistive element 51, and a second electrode 52 are formed in this order on the non-ohmic element 49. Therefore, the barrier metal 48 to a second electrode 52 are formed as the memory cell MC. A gap between the memory cells MC adjacent to each other is buried with a second interlayer insulator and a third interlayer insulator 55 (however, the second interlayer insulator is not illustrated in FIG. 3). A second metal 56 is formed on each memory cell MC of the memory cell array, and the second metal 56 constitutes the bit line BLi extended in a direction orthogonal to the word line WLi. Thus, the nonvolatile memory that is of the variable resistive memory is formed. The formation of the barrier metal 48 to the upper electrode 52 and the formation of the second interlayer insulator and third interlayer insulator 55 between the memory cells MC may be repeated by the number of necessary layers in order to implement the multilayer structure.

### Exposure Method of First Embodiment

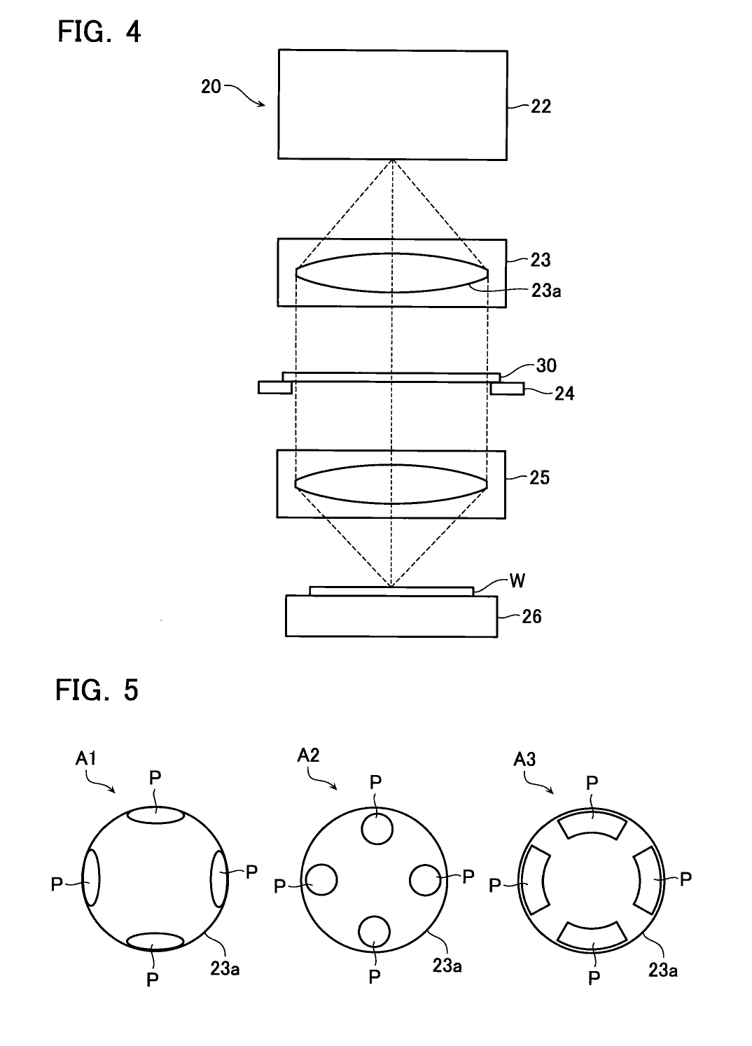

The exposure method of the first embodiment will be described. The exposure method of the first embodiment is used in forming the memory cell MC (columnar portion). An exposure apparatus 20 used in the exposure method of the first embodiment will be described with reference to FIGS. 4 and 5. FIG. 4 schematically illustrates the exposure apparatus 20 used in the exposure method of the first embodiment. FIG. 5 illustrates an example of quadrupole illumination.

Referring to FIG. 4, the exposure apparatus 20 typically includes a light source optical system 22, an illumination optical system 23, a photomask stage 24, a projection optical system 25, and a wafer stage 26.

The light source optical system 22 includes a light source. The light source optical system 22 is configured such that quadrupole illumination is formed in a secondary light source surface 23a of the illumination optical system 23. As illustrated in illumination regions P of the numerals A1 to A3 of FIG. 5, in the quadrupole illumination, the light is emitted from four positions of the secondary light source surface 23a.

The illuminating light transmitted through the illumination optical system 23 reaches the wafer stage 26 through the photomask stage 24 and the projection optical system 25.

The halftone mask 30 used to expose a wafer (substrate) W can be placed on the photomask stage 24.

The wafer W can be placed on the wafer stage 26. The columnar portion (memory cell MC) is formed on the wafer W by the exposure.

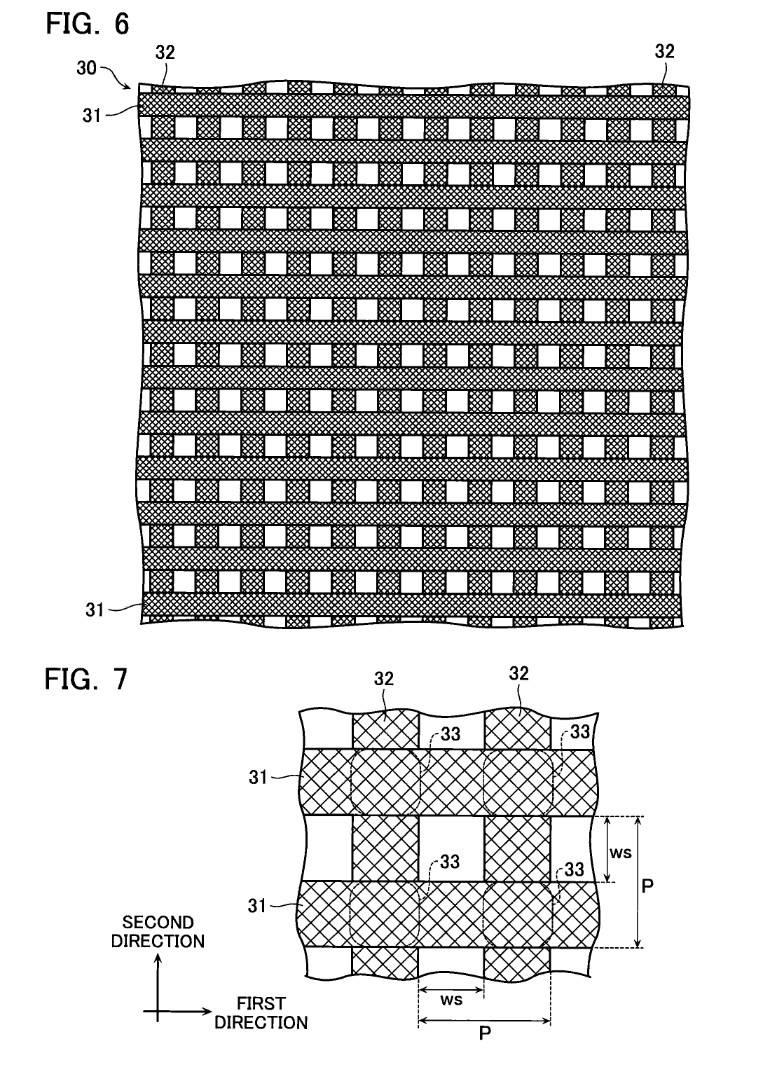

A configuration of the halftone mask 30 will be described with reference to FIGS. 6 and 7. FIG. 6 is a plan view illustrating the halftone mask 30 used in the exposure method, and FIG. 7 is an enlarged view illustrating the halftone mask 30 of FIG. 6.

Referring to FIG. 6, the halftone mask 30 includes a first pattern 31 and a second pattern 32. The first pattern 31 is extended in the first direction and disposed at predetermined pitches in the second direction. The second pattern 32 is extended in the second direction and disposed at predetermined pitches in the first direction. The second pattern 32 is formed so as to have an intersection portion 33 intersecting the first pattern 31. The second direction is orthogonal to the first direction.

In the halftone mask 30, the first and second patterns 31 and 32 are formed with a pitch P and a spacing ws. The halftone mask 30 is formed such that zero-order diffracted light intensity and first-order diffracted light intensity that are diffracted by the halftone mask 30 are substantially matched with each other, and the halftone mask 30 is formed such that a first-order diffracted light phase is inverted with respect to a zero-order diffracted light phase. The halftone mask 30 satisfies a relationship expressed by (Formula 9) that is explained later.

The halftone mask 30 has a transmittance of 6% to 18%. For example, when the halftone mask 30 has the transmittance of 6%, a complex transmittance t can be computed by (Formula 3). Hereinafter the halftone mask 30 has a transmittance of x % is referred to as “x % HT”.

t=\sqrt{0.06}×exp(iπ)≈−0.24495 (Formula 3)

A condition that the diffracted light having the maximum contrast is generated in the halftone mask 30 will be described. A complex transmittance distribution m(x,y) of the halftone mask 30 used in the exposure method of the first embodiment is expressed by (Formula 4). A complex transmittance distribution m̂(f,g) after performing a Fourier transform is expressed by (Formula 5). In the following description, “FT” in (Formula 5) indicates the Fourier transform.

$$\begin{matrix}m ( x , y ) = t \times rect ( \frac{x}{P} ) rect ( \frac{y}{P} ) ⊗ comb ( \frac{x}{P} ) comb ( \frac{y}{P} ) + ( 1 - t ) rect ( \frac{x}{ws} ) rect ( \frac{y}{ws} ) ⊗ comb ( \frac{x - P / 2}{P} ) comb ( \frac{y - P / 2}{P} ) & ( Formula 4 ) \\ \begin{matrix}\hat{m} ( f , g ) = FT [ m ( x , y ) ] \\ = {tP}^{2} sin c ( Pf ) sin c ( Pg ) \cdot comb ( Pf ) comb ( Pg ) + \\ ( 1 - t ) {w}_{s}^{2} sin c ( {w}_{s} f ) sin c ( {w}_{s} g ) \times comb ( Pf ) \\ comb ( Pg ) exp ( π i P ( f + g ) )\end{matrix} & ( Formula 5 )\end{matrix}$$

A complex transmittance distribution m̂(0,0) after performing the Fourier transform by the zero-order diffracted light is expressed by (Formula 6), and complex transmittance distributions m̂(0,±1/P) and m̂(±1/P,0) after performing the Fourier transform by the first-order diffracted light is expressed by (Formula 7):

$$\begin{matrix}\hat{m} ( 0 , 0 ) = {tP}^{2} + ( 1 - t ) \times {w}_{s}^{2} & ( Formula 6 ) \\ \hat{m} ( 0 , \pm \frac{1}{P} ) = \hat{m} ( \pm \frac{1}{P} , 0 ) = ( 1 - t ) \times {w}_{s}^{2} sin c ( \frac{{w}_{s}}{P} ) & ( Formula 7 )\end{matrix}$$

On the condition that the contrast between the zero-order diffracted light and the first-order diffracted light becomes the maximum, the zero-order diffracted light intensity is equal to the first-order diffracted light intensity and the first-order diffracted light phase is inverted with respect to the zero-order diffracted light phase. That is, the contrast becomes the maximum on the condition satisfying (Formula 8):

$$\hat{m} ( 0 , \pm \frac{1}{P} ) = \hat{m} ( \pm \frac{1}{P} , 0 ) = - \hat{m} ( 0 , 0 ) \qquad ( Formula 8 )$$

A relationship expressed by (Formula 9) is obtained when the relationships expressed by (Formula 6) and (Formula 7) are substituted for (Formula 8):

$${tP}^{2} + ( 1 - t ) \times {w}_{s}^{2} = ( 1 - t ) \times {w}_{s}^{2} sin c ( \frac{{w}_{s}}{P} ) \qquad ( Formula 9 )$$

A relationship expressed by (Formula 11) is derived when a relationship expressed by (Formula 10) is substituted for (Formula 9):

$$\begin{matrix}{X}_{s} = \frac{{w}_{s}}{P} & ( Formula 10 ) \\ \frac{t}{( t - 1 ) {X}_{s}^{2}} = 1 - sin c ( {X}_{s} ) & ( Formula 11 )\end{matrix}$$

Assuming that f(Xₛ) is a left-hand side of (Formula 11) and g(Xₛ) is a right-hand side of (Formula 11), f(Xₛ) and g(Xₛ) can be expressed by (Formula 12) and (Formula 13):

$$\begin{matrix}f ( {X}_{s} ) = \frac{t}{( t - 1 ) {X}_{s}^{2}} & ( Formula 12 ) \\ g ( {X}_{s} ) = 1 - sin c ( {X}_{s} ) & ( Formula 13 )\end{matrix}$$

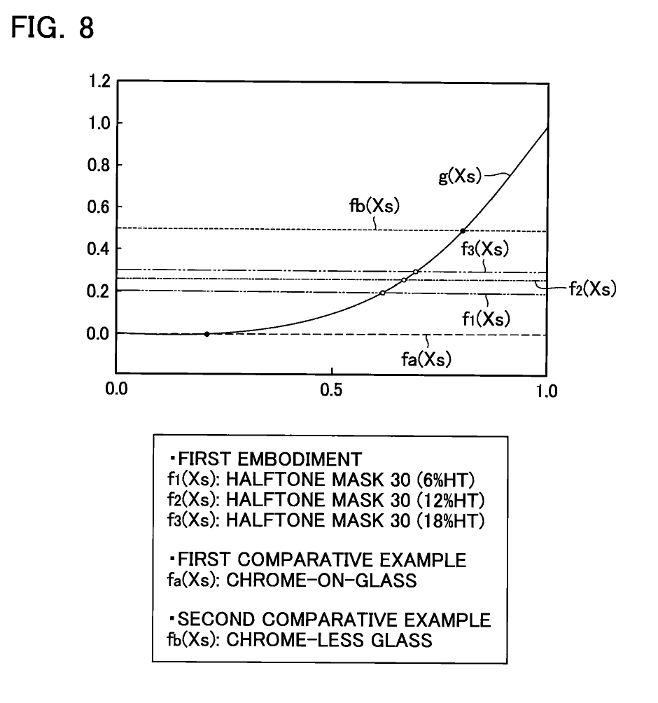

FIG. 8 illustrates a function of g(Xₛ). FIG. 8 also illustrates f₁(Xₛ) to f₃(Xₛ), fₐ(Xₛ), and f_{b}(Xₛ). f₁(Xₛ) to f₃(Xₛ) indicate f(Xₛ) in which a characteristic complex transmittance t of halftone mask 30 (6% HT, 12% HT, and 18% HT) of the first embodiment are substituted. fₐ(Xₛ) and f_{b}(Xₛ) indicate f(Xₛ) of first and second comparative examples of the first embodiment. The first comparative example (fₐ(Xₛ)) is a pattern similar to that of the halftone mask 30 of the first embodiment, and the first comparative example (fₐ(Xₛ)) is formed by a Chrome-On-Glass (COG) mask. The second comparative example (f_{b}(Xₛ)) has a shape similar to that of the halftone mask 30 of the first embodiment, and the second comparative example (f_{b}(Xₛ)) is formed by a chrome-less mask.

As can be seen from (Formula 11) to (Formula 13), in FIG. 8, an intersection Xₛ between f₁(Xₛ) to f₃(Xₛ) and g(Xₛ) becomes the condition that the contrast between the zero-order diffracted light and the first-order diffracted light is maximized. The same condition also holds in the first and second comparative examples.

As illustrated in FIG. 8, in the case of the halftone mask 30 (6% HT), “Xₛ=0.62” is the condition that the contrast is maximized. “Xₛ=0.62” means that “a minimum spacing between the patterns is 0.38 time the pitch.” At this point, the minimum dimension on the mask production is guaranteed by about a half of the pattern pitch necessary for the device.

### Method for Producing Semiconductor Device of First Embodiment

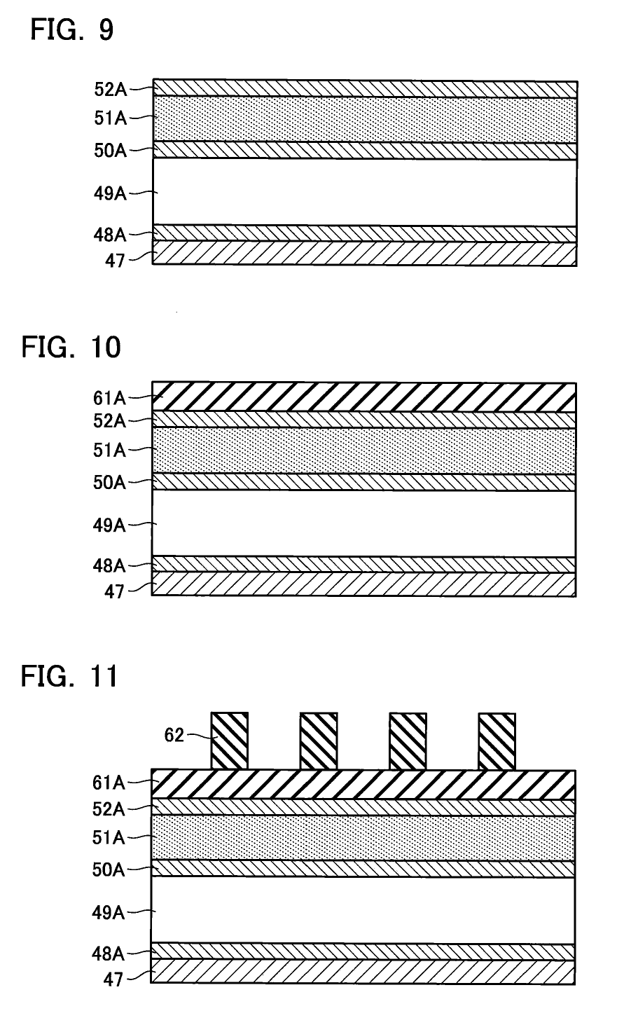

A method for producing the semiconductor device of the first embodiment will be described with reference to FIGS. 9 to 15. FIGS. 9 to 15 are sectional views illustrating a process for producing the semiconductor device of the first embodiment. The halftone mask 30 is used in the method for producing the semiconductor device of the first embodiment. FIGS. 9 to 15 illustrate the upper layers from the first metal 47 (see FIG. 3).

First, the first interlayer insulator 45 and the first metal 47 are formed. At this point, an interlayer insulator is deposited between the first metals 47 separated from each other in the pitch direction (not illustrated). Then a layer 48A constituting the barrier metal 48, a layer 49A constituting the non-ohmic element 49, a layer 50A constituting the first electrode 50, a layer 51A constituting the variable resistive element 51, and a layer 52A constituting the second electrode 52 are sequentially deposited on the first metal 47. Therefore, a laminated structure illustrated in FIG. 9 is formed.

As illustrated in FIG. 10, a hard mask 61A is deposited on the layer 52A.

As illustrated in FIG. 11, a resist 62 is formed on the hard mask 61A. The resist 62 is formed using the halftone mask 30. That is, the resist 62 is formed into a matrix shape.

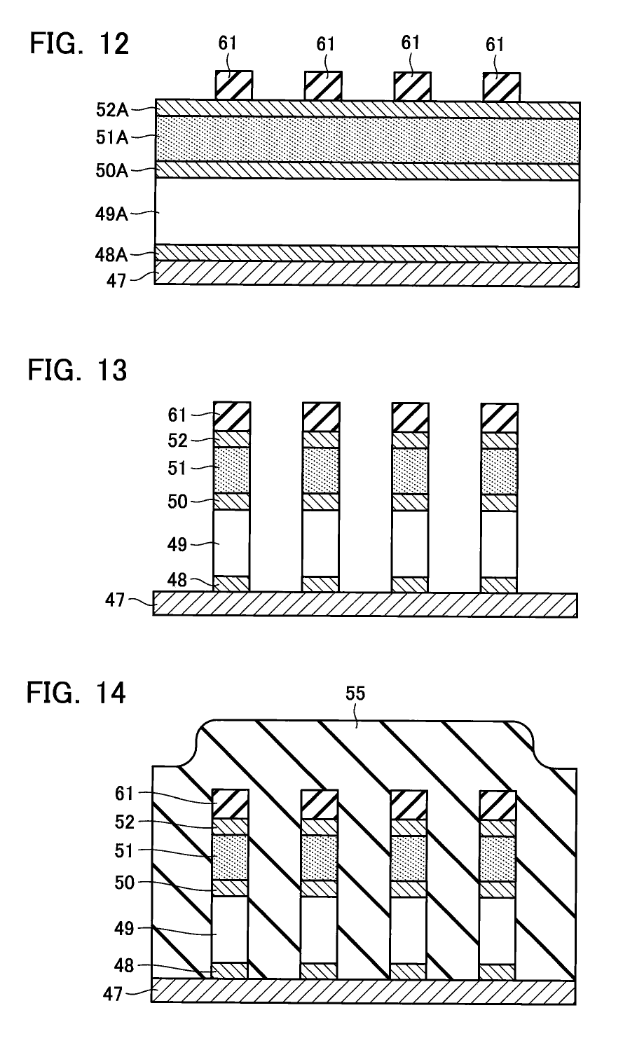

As illustrated in FIG. 12, the hard mask 61A is etched to form the columnar hard mask 61 with the resist 62 as a mask. The resist 62 is removed after the etching.

As illustrated in FIG. 13, the layers 48A to 52A are etched to form the columnar barrier metal 48, the non-ohmic element 49, the first electrode 50, the variable resistive element 51, and the second electrode 52 with the hard mask 61 as a mask.

As illustrated in FIG. 14, the second interlayer insulator and the third interlayer insulator 55 are deposited such that the gap between the columnar barrier metals 48, non-ohmic elements 49, first electrode 50, variable resistive elements 51, and second electrodes 52 is buried therewith.

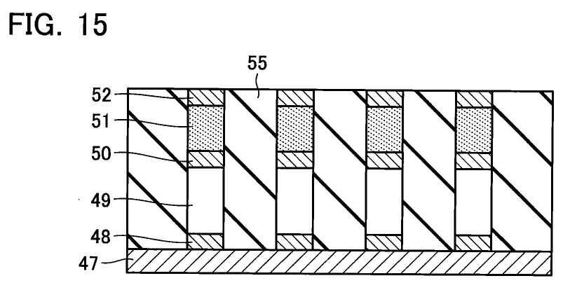

As illustrated in FIG. 15, a CMP process is performed to perform planarization to an upper surface of the second electrode 52. Then a process is further performed to form the laminated structure of FIG. 3.

### Effect of Exposure Method of First Embodiment

A comparative example is discussed to explain an effect of the exposure method of the first embodiment. In the comparative example, a shape of a halftone mask is different from that of the first embodiment. The halftone mask of the comparative example has the shape in which rectangular-island-like light-shielding portions are independently disposed into a matrix shape. In the case of the halftone mask of the comparative example, “Xₛ=0.81” is the condition that the contrast is maximized. “Xₛ=0.81” means that “the minimum spacing between the patterns is 0.19 time the pitch.” That is, when the exposure is performed using the halftone mask of the comparative example, there is a risk of generating a defect in the exposed pattern.

On the other hand, as described above, the contrast is maximized at “Xₛ=0.62” in the halftone mask 30 (6% HT) of the first embodiment. Accordingly, when the exposure is performed using the halftone mask 30, the generation of the defect in the exposed pattern can be prevented compared with the comparative example.

### Second Embodiment

### Exposure Method of Second Embodiment

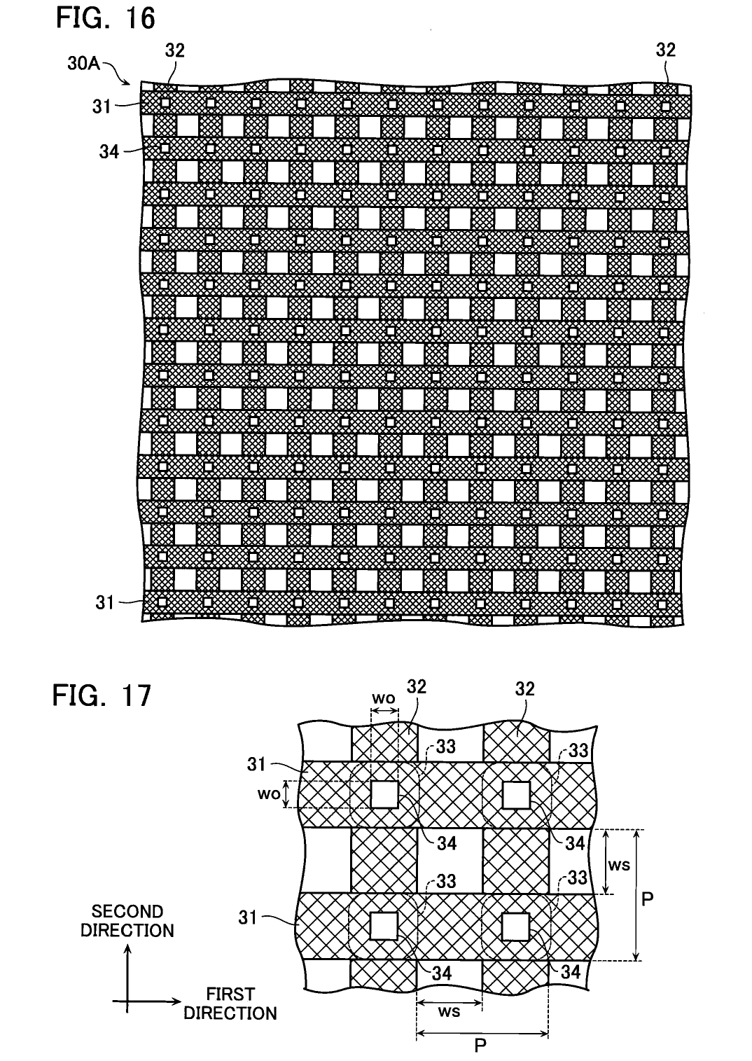

An exposure method according to a second embodiment of the invention will be described below with reference to FIGS. 16 and 17. A halftone mask 30A different from that of the first embodiment is used in the exposure method of the second embodiment. FIG. 16 is a plan view illustrating the halftone mask 30A, and FIG. 17 is an enlarged view illustrating the halftone mask 30A of FIG. 16. In the second embodiment, a configuration similar to that of the first embodiment is designated by the same numeral, and the description is omitted.

Referring to FIGS. 16 and 17, as with the first embodiment, the halftone mask 30A includes the first pattern 31 and the second pattern 32. Unlike the first embodiment, the halftone mask 30A has an opening 34 near the intersection portion 33. A center of the opening 34 is matched with a center of the intersection portion 33.

In the halftone mask 30A, the first and second patterns 31 and 32 have the pitches and spacings similar to those of the first embodiment. The opening 34 is formed into a square shape with a length of one side being wo. The halftone mask 30A is formed so as to satisfy a relationship expressed by (Formula 18) later.

The condition that the diffracted light having the maximum contrast is generated in the halftone mask 30A will be described. A complex transmittance distribution m(x,y) of the halftone mask 30A used in the exposure method of the second embodiment is expressed by (Formula 14). A complex transmittance distribution m̂(f,g) after performing the Fourier transform is expressed by (Formula 15):

$$\begin{matrix}m ( x , y ) = t \times rect ( \frac{x}{P} ) rect ( \frac{y}{P} ) ⊗ comb ( \frac{x}{P} ) comb ( \frac{y}{P} ) + ( 1 - t ) rect ( \frac{x}{ws} ) rect ( \frac{y}{ws} ) ⊗ comb ( \frac{x - P / 2}{P} ) comb ( \frac{y - P / 2}{P} ) + ( 1 - t ) rect ( \frac{x}{wo} ) rect ( \frac{y}{wo} ) ⊗ comb ( \frac{x}{P} ) comb ( \frac{y}{P} ) & ( Formula 14 ) \\ \begin{matrix}\hat{m} ( f , g ) = FT [ m ( x , y ) ] \\ = {tP}^{2} sin c ( Pf ) sin c ( Pg ) \cdot comb ( Pf ) \\ comb ( Pg ) + ( 1 - t ) {w}_{s}^{2} sin c ( {w}_{s} f ) sin c ( {w}_{s} g ) \times \\ comb ( Pf ) comb ( Pg ) exp ( π i P ( f + g ) ) + ( 1 - t ) \\ {w}_{o}^{2} sin c ( {w}_{o} f ) sin c ( {w}_{o} g ) \times comb ( Pf ) comb ( Pg )\end{matrix} & ( Formula 15 )\end{matrix}$$

A complex transmittance distribution m̂(0,0) after performing the Fourier transform by the zero-order diffracted light is expressed by (Formula 16), and complex transmittance distributions m̂(0,±1/P) and m̂(±1/P,0) after performing the Fourier transform by the first-order diffracted light are expressed by (Formula 17):

$$\begin{matrix}\hat{m} ( 0 , 0 ) = {tP}^{2} + ( 1 - t ) \times {w}_{s}^{2} + ( 1 - t ) \times {w}_{o}^{2} & ( Formula 16 ) \\ \begin{matrix}\hat{m} ( 0 , \pm \frac{1}{P} ) = \hat{m} ( \pm \frac{1}{P} , 0 ) \\ = ( 1 - t ) \times {w}_{s}^{2} sin c ( \frac{{w}_{s}}{P} ) + \\ ( 1 - t ) \times {w}_{o}^{2} sin c ( \frac{{w}_{o}}{P} )\end{matrix} & ( Formula 17 )\end{matrix}$$

As with the first embodiment, the condition that the contrast between the zero-order diffracted light and the first-order diffracted light becomes the maximum can be expressed by (Formula 8). When the relationships of (Formula 16) and (Formula 17) are substituted for (Formula 8), a relationship expressed by (Formula 18) is obtained:

$${tP}^{2} + ( 1 - t ) \times {w}_{s}^{2} + ( 1 - t ) \times {w}_{o}^{2} = ( 1 - t ) \times {w}_{s}^{2} sin c ( \frac{{w}_{s}}{P} ) - ( 1 - t ) \times {w}_{o}^{2} sin c ( \frac{{w}_{o}}{P} ) \qquad ( Formula 18 )$$

When the relationship of (Formula 19) is substituted for (Formula 18), a relationship expressed by (Formula 20) can be derived:

$$\begin{matrix}{X}_{s} = \frac{{w}_{s}}{P} , {X}_{o} = \frac{{w}_{o}}{P} & ( Formula 19 ) \\ \frac{- t}{( 1 - t )} = {X}_{s}^{2} ( 1 - sin c ( {X}_{s} ) ) + {X}_{o}^{2} ( 1 + sin c ( {X}_{o} ) ) & ( Formula 20 )\end{matrix}$$

At this point, it is assumed that the right-hand side of (Formula 20) is h(Xₛ,Xₒ) of (Formula 21):

h(Xₛ,Xₒ)=Xₛ²(1−sin c(Xₛ))+X₀²(1+sin c(Xₒ)) (Formula 21)

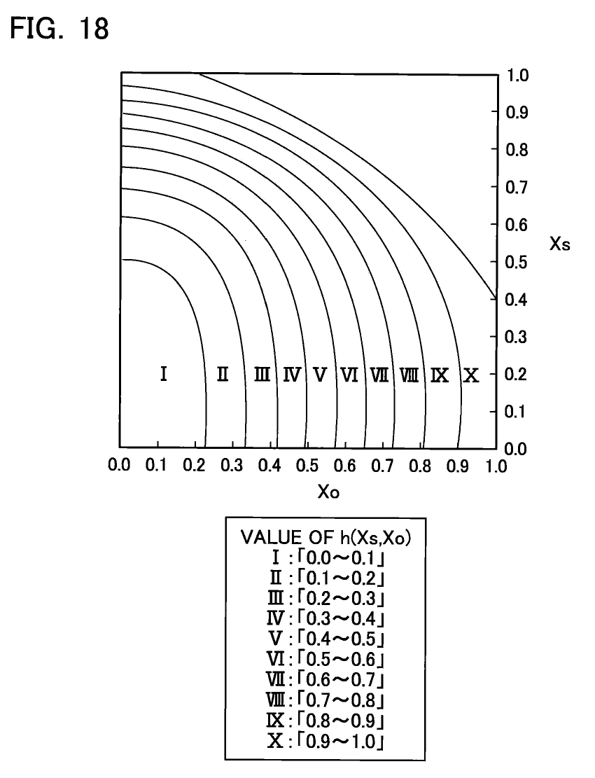

FIG. 18 illustrates a level line of the value of h(Xₛ,Xₒ) In FIG. 18, a horizontal axis indicates Xₒ, and a vertical axis indicates Xₛ. In FIG. 18, regions designated by the numerals “I” to “X” indicate that the values of h(Xₛ,Xₒ) fall within the following ranges: The numeral “I” designates the range of “0.0 to 0.1”. The numeral “II” designates the range of “0.1 to 0.2”. The numeral “III” designates the range of “0.2 to 0.3”. The numeral “IV” designates the range of “0.3 to 0.4”. The numeral “V” designates the range of “0.4 to 0.5”. The numeral “VI” designates the range of “0.5 to 0.6”. The numeral“VII” designates the range of “0.6 to 0.7”. The numeral “VIII” designates the range of “0.7 to 0.8”. The numeral “IX” designates the range of “0.8 to 0.9”. The numeral “X” designates the range of “0.9 to 1.0”.

For example, when the halftone mask 30A of (6% HT) is used, the value of the left-hand side of (Formula 18) becomes about “0.197”. Accordingly, the exposure contrast of the halftone mask 30A is maximized on a curve satisfying “h(Xₛ,Xₒ)≈0.197” in the region of the numeral “II” of FIG. 18.

### Effect of Exposure Method of Second Embodiment

The effect of the exposure method of the second embodiment will be described. When the exposure method of the second embodiment is used, the values of Xₒ(=wo/P) and Xₛ(=ws/P) are set in consideration of the complex transmittance t, which allows the exposure contrast to be maximized. The columnar portion to be formed can partially eliminated by locally setting the value of Xₒ larger.

### Third Embodiment

### Exposure Method of Third Embodiment

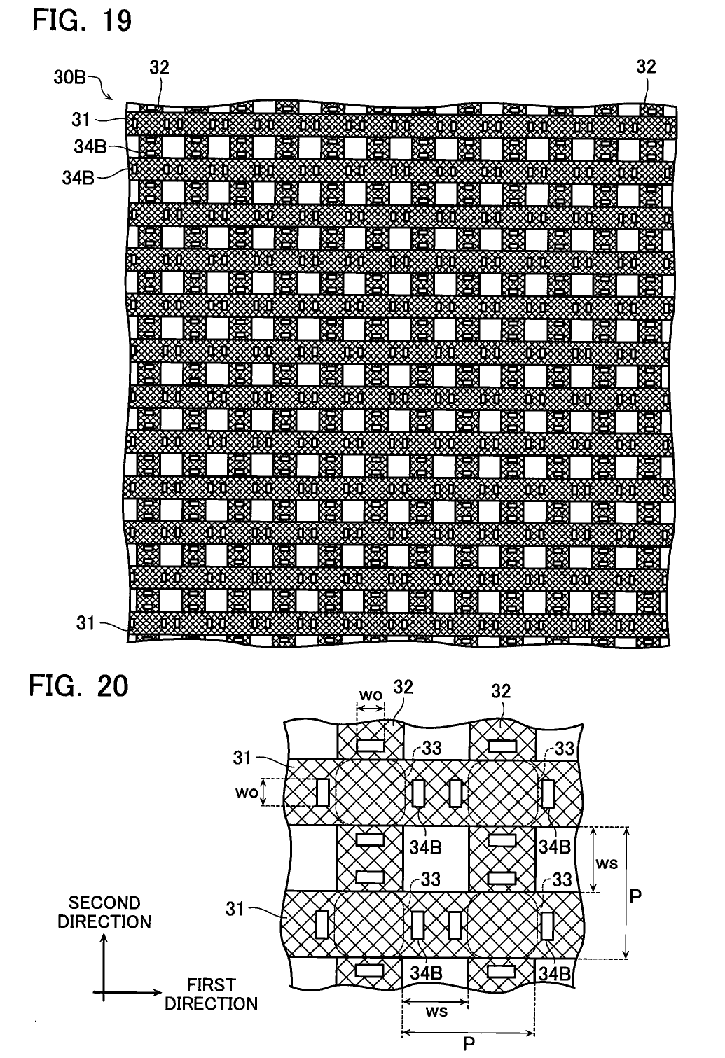

An exposure method according to a third embodiment of the invention will be described below with reference to FIGS. 19 and 20. A halftone mask 30B different from those of the first and second embodiments is used in the exposure method of the third embodiment. FIG. 19 illustrates the halftone mask 30B of the third embodiment, and FIG. 20 is an enlarged view illustrating the halftone mask 30B of FIG. 20. In the third embodiment, a configuration similar to that of the first and second embodiments is designated by the same numeral, and the description is omitted.

Referring to FIGS. 19 and 20, as with the first and second embodiments, the halftone mask 30B includes the first pattern 31 and the second pattern 32. The halftone mask 30B has an opening 34B near the intersection portion 33. The opening 34B is located on the first and the second patterns 31 and 32 that are adjacent to the intersection portion 33.

The exposure method of the third embodiment has the effect similar to that of the second embodiment.

### Fourth Embodiment

### Exposure Method of Fourth Embodiment

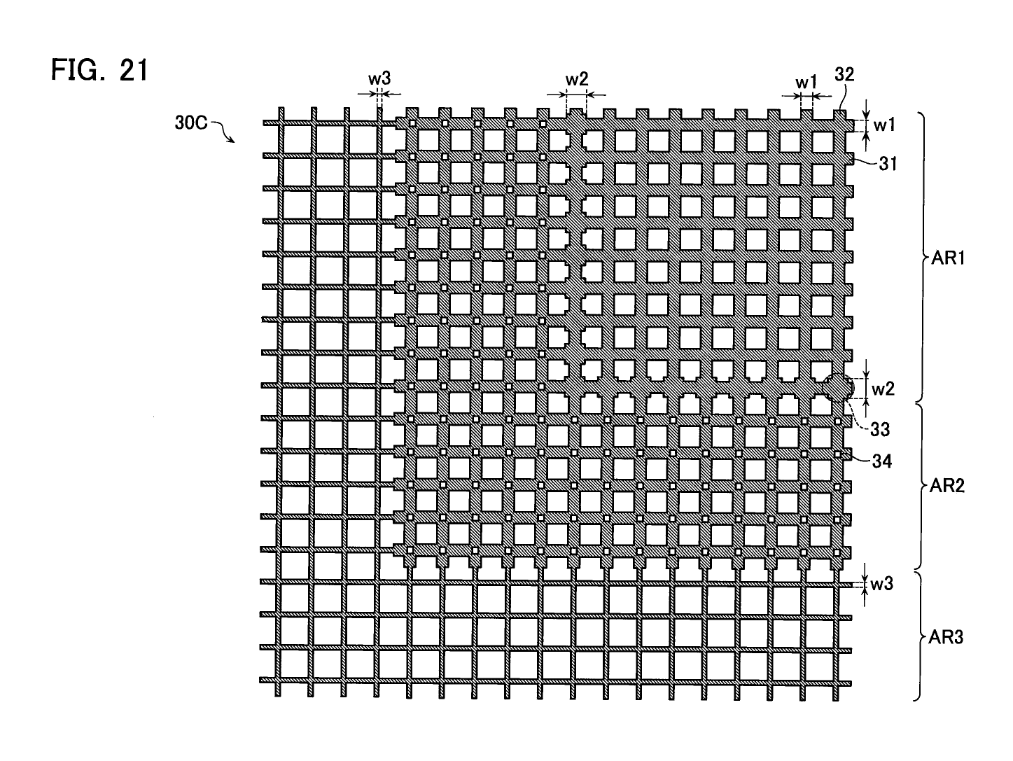

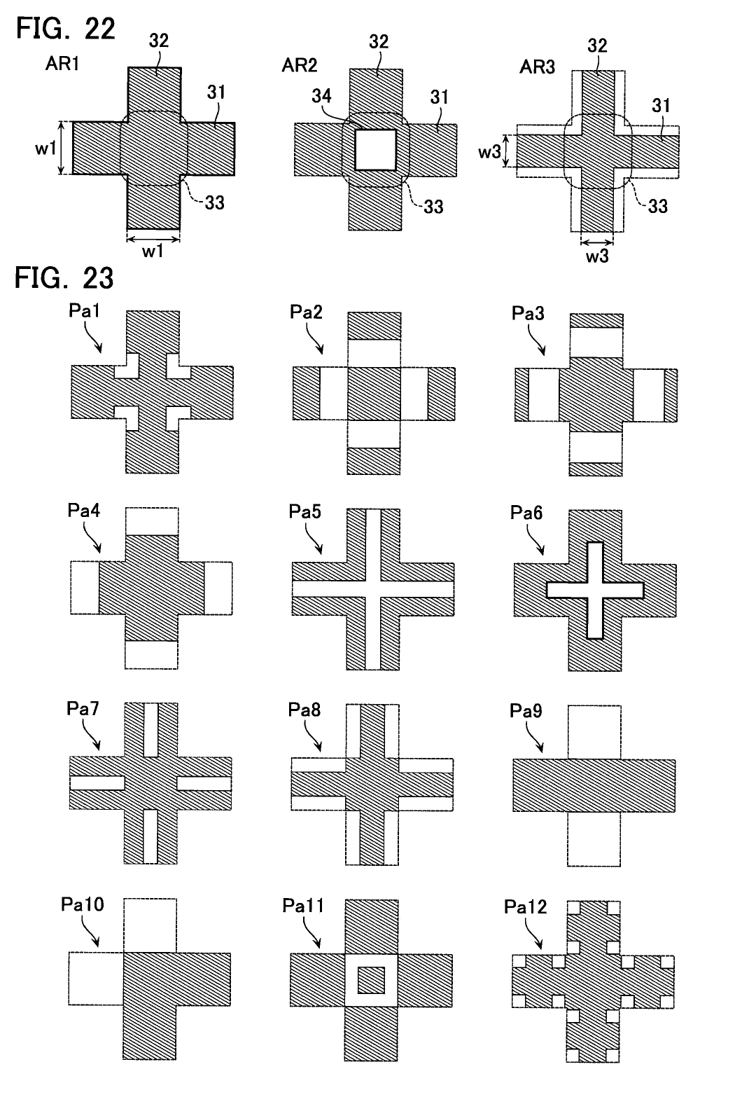

An exposure method according to a fourth embodiment of the invention will be described below with reference to FIGS. 21 and 22. A halftone mask 30C different from that of the first to third embodiments is used in the exposure method of the fourth embodiment. FIG. 21 illustrates the halftone mask 30C of the fourth embodiment, and FIG. 22 is an enlarged view illustrating a neighborhood of the intersection portion 33 of FIG. 21. In the fourth embodiment, a configuration similar to those of the first to third embodiments is designated by the same numeral, and the description is omitted.

Referring to FIGS. 21 and 22, the halftone mask 30C of the fourth embodiment includes first to third regions AR1 to AR3. The first region AR1 is a rectangular region. The second region AR2 is formed so as to surround the first region AR1. The third region AR3 is formed so as to surround the second region AR2.

In the first region AR1, the halftone mask 30C has the configuration of the first embodiment, and the columnar portion can be formed by the exposure using the halftone mask 30C. In the first region AR1, the halftone mask 30C has a pattern that is different from those of the second and third regions AR2 and AR3. In the first region AR1, the first and second patterns 31 and 32 are formed with a first width w1. In the first region AR1, the intersection portion 33 adjacent to the second region AR2 is formed with a second width w2 (w2>w1) and used in the OPC process.

In the second region AR2, the halftone mask 30C has the configuration of the second embodiment, and the columnar portion is not formed by the exposure using the halftone mask 30C. In the second region AR2, the halftone mask 30C has a pattern that is different from those of the first and third regions AR1 and AR3. In the second region AR2, the first and second patterns 31 and 32 are formed with the first width w1. In the second region AR2, the halftone mask 30C has the opening 34 in the intersection portion 33.

In the third region AR3, the halftone mask 30C has the configuration of the first embodiment, and the columnar portion is not formed by the exposure using the halftone mask 30C. In the third region AR3, the halftone mask 30C has a pattern that is different from those of the first and second regions AR1 and AR2. In the third region AR3, the first and second patterns 31 and 32 are formed with a third width w3 (w3<w1).

### Effect of Exposure Method of Fourth Embodiment

An effect of the exposure method of the fourth embodiment will be described in comparison with the first to third embodiments. The halftone masks 30, 30A, and 30B of the first to third embodiments are entirely formed with a constant pattern. Therefore, the optical contrast and the lithography margin are lowered at end portions of the halftone masks 30, 30A, and 30B.

On the other hand, the halftone mask 30C of the fourth embodiment includes the first to third regions AR1 to AR3 having the different patterns unlike the first to third embodiments. Accordingly, in the halftone mask 30C, the problems such as the lowering of the optical contrast and the lowering of the lithography margin, which are generated in the first to third embodiments, can be solved by the first to third regions AR1 to AR3.

### Other Embodiment

The first to fourth embodiments are described above. The invention is not limited to the first to fourth embodiments, but various modifications, additions, substitutions can be made without departing from the scope of the invention.

Although the halftone mask 30 has the transmittances of 6%, 12%, and 18% in the first embodiment, the invention is not limited to the transmittances of 6%, 12%, and 18%. A mask having a pattern similar to that of the halftone mask 30 may be used instead of the halftone mask 30. The condition that the contrast is maximized in the mask is obtained by the transmittance and the pitch of the mask. At this point, the condition reflecting an exact analysis may be obtained in consideration of the restriction of the exposure amount, the restriction of the mask production, and a mask topography effect. For example, the condition that the contrast is maximized may be set to “0.31≦Xₛ≦0.69”.

The columnar portion that is formed by the exposure method of the invention is not limited to the memory cell MC of the first embodiment. The columnar portion that is formed by the exposure method of the invention may be used as part of another circuit.

For example, the mask patterns near the intersection portions 33 of the second and third embodiments, the second region AR2 of the fourth embodiment, the mask pattern near the intersection portion 33 of the third region AR3 may be patterns Pa1 to Pa12 of FIG. 23.

What is claimed is:

1. An exposure method comprising an exposure process for exposing a substrate through a halftone mask with quadrupole illumination to form a plurality of columnar portions that are disposed into a matrix shape in a first direction and a second direction orthogonal to the first direction,
the halftone mask including:
a first pattern extended in the first direction and disposed at predetermined pitches in the second direction; and
a second pattern extended in the second direction and disposed at predetermined pitches in the first direction such that an intersection portion intersecting the first pattern is formed, and
the pitches and widths of the patterns on the halftone mask being configured such that zero-order diffracted light intensity and first-order diffracted light intensity, which are diffracted by the halftone mask, are substantially matched with each other and such that a first-order diffracted light phase is inverted with respect to a zero-order diffracted light phase.

2. The exposure method according to claim 1, wherein a relationship expressed by (Formula 1) is satisfied in the case of “Xₛ=ws/P”:
$$\frac{t}{( t - 1 ) {X}_{s}^{2}} = 1 - sin c ( {X}_{s} ) \qquad ( Formula 1 )$$
where “P” is a pitch of the pattern on the halftone mask, “ws” is a width of the pattern on the halftone mask, and “t” is a complex transmittance of the halftone mask.

3. The exposure method according to claim 1, wherein the halftone mask comprises an opening provided near the intersection portion.

4. The exposure method according to claim 3, wherein a center of the opening is located in a center of the intersection portion.

5. The exposure method according to claim 3, wherein the opening is located on the first and the second patterns that are adjacent to the intersection portion.

6. The exposure method according to claim 3, wherein the opening has a square shape.

7. The exposure method according to claim 1, wherein the halftone mask comprises:
a first region formed such that the plurality of columnar portions can be exposed; and
a second region formed so as to surround the first region, the second region having a pattern different from that of the first region.

8. The exposure method according to claim 7, wherein the intersection portion of the first region that is adjacent to the second region is used in an OPC process.

9. The exposure method according to claim 8, wherein a width of the intersection portion of the first region that is adjacent to the second region is formed longer than a width of the first pattern of the first region and a width of the second pattern of the first region.

10. A semiconductor device comprising a plurality of columnar portions extended in a direction perpendicular to a substrate, and disposed into a matrix shape at equal pitches in a predetermined region,
wherein relationships expressed by (Formula 2) and (Formula 3) are satisfied:
1.1μ₂>μ₁>μ₂ (Formula 2)
0<α₁−α₂ (Formula 3)
where μ₁ is an average value of diameters of the columnar portions formed in an end portion of the predetermined region, α₁ is a variation of diameters of the columnar portions formed in the end portion of the predetermined region, μ₂ is an average value of diameters of the columnar portions formed in a portion except for the end portion of the predetermined region, and α₂ is a variation of diameters of the columnar portions formed in a portion except for the end portion of the predetermined region.

11. The semiconductor device according to claim 10, wherein the columnar portion acts as a variable resistive element and a non-ohmic element, which are connected in series.
